(19) United States
(12) Patent Application Publication
(10) Pub. No.: US 2007/0170444 A1
(43) Pub. Date: Jul. 26, 2007

(54) Integrated LED Chip to Emit Multiple Colors and Method of Manufacturing the Same

(75) Inventor: Densen Cao, Sandy, UT (US)

Correspondence Address: GEOFFREY E. DOBBIN, PATENT ATTORNEY, 4278 SOUTH 6220 WEST, WEST VALLEY CITY, UT, 84128-6501, US

(73) Assignee: CAO GROUP, INC., West Jordan, UT (US)

(21) Appl. No.: 11/689,233

(22) Filed: Mar. 21, 2007

Related U.S. Application Data
(63) Continuation-in-part of application No. 11/176,696, filed on Jul. 7, 2005.
(60) Provisional application No. 60/585,988, filed on Jul. 7, 2004.

(51) Int. Cl. H01L 33/00; H01L 21/00

(52) U.S. Cl. 257/89; 438/28; 257/E33.012

(57) ABSTRACT

The present invention is a monolithic, multi-colored LED chip and a method for making the same. The LED chip is comprised of a substrate and a plurality of light emitting structures, each light emitting structure capable of emitting a wavelength of light unique compared to others and each structure layered on top of another structure and separated by a dielectric layer. The light emitting structures are then capable of independent or tandem activation, yielding the original colors of each section, blends of colors, and white light. The method starts with the base for such a chip and etches layers of the chip away, leaving exposed sections, to reach electrical contact layers for each light emitting structure. Electrically conductive material is then used to fill the exposed sections and is, in turn, etched away to leave contacts. An insulating material is then used to fill in the resultant areas.

### CROSS-REFERENCES TO RELATED APPLICATIONS

This invention is a continuing-in-part application of application Ser. No. 11/176,696, filed on Jul. 7, 2005 and published as publication number 20060027820 on Feb. 9, 2006. It, in turn, claims priority on prior filed provisional application 60/585,988, filed Jul. 7, 2004. This Application claims priority on both and incorporates the same herein by reference in their entirety.

### FIELD OF THE INVENTION

The present invention relates to the field of LED chips and more particularly relates to the field of LED chips capable of generating multiple colors.

### BACKGROUND OF THE INVENTION

Light emitting diodes (LEDs) will be the source for next generation lighting. White light and other color LEDs will be essential for different applications. Currently, the each LED chip is emitting one individual color. Multiple colors including white are generated through mixing of different color chips or combine second step excitation. For example, white LED can be generated by mixing red, green, and blue, or using blue or UV chips to excite phosphor.

One chip in the prior art, U.S. Pat No. 6,060,727 (2000) to Shakuda, places multiple colored LED chip fragments on a single substrate to create a multiple colored single LED chip. These fragments are, however, adjacent to each other and the resultant LED chip is not comprised of one set of epitaxial layers.

In the parent Application, an invention to produce an integrated chip containing red, green, and blue emissions in one chip by one step epitaxial process was disclosed. A trench structure has been disclosed to make electrical contracts for each LED structures.

In this invention, new LED structures using one step epitaxial process to integrate red, green, and blue emitting structures together in one chip with different contact formats to emit multiple colors, are disclosed.

### SUMMARY OF THE INVENTION

In view of the foregoing disadvantages inherent in the known types of LED chips, this invention provides a multi-colored LED chip. As such, the present invention's general purpose is to provide a new and improved multi-colored LED chip that is easily manufactured with a single step epitaxial process and with easily accomplished etching techniques to install electrical connectors to the same.

In its basic construction, the LED chip comprises a single substrate with a plurality of light emission structures stacked on top of the substrate. Each light emission structure is isolated from each other with an isolation layer or dielectric layer and each emits a different color. Electrical contacts are positioned by first etching away proper layers in each emitting structure to allow for the contacts to be positioned appropriately for each emitting structure and filling the etched portions with conductive material. The conductive material is then etched to form the required contacts and the resultant space filled with an insulating material. Thus, each light emitting structure can be individually controlled per requirements.

The more important features of the invention have thus been outlined in order that the more detailed description that follows may be better understood and in order that the present contribution to the art may better be appreciated. Additional features of the invention will be described hereinafter and will form the subject matter of the claims that follow.

Many objects of this invention will appear from the following description and appended claims, reference being made to the accompanying drawings forming a part of this specification wherein like reference characters designate corresponding parts in the several views.

Before explaining at least one embodiment of the invention in detail, it is to be understood that the invention is not limited in its application to the details of construction and the arrangements of the components set forth in the following description or illustrated in the drawings. The invention is capable of other embodiments and of being practiced and carried out in various ways. Also it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods, and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

FIG. 1 is a sectional view of the epitaxial structure of an LED chip manufactured by a one-step epitaxial process for the first stage of the process according to the present invention.

FIG. 2 is a series of sectional views of the manufacturing process according to the present invention.

FIG. 3 is a sectional view of a multiple color emitting chip after undergoing the process depicted in FIG. 2.

FIGS. 4a and 4b are top plan views of completed chips according to the present invention.

### DETAILED DESCRIPTION OF THE PREFERRED EMBODIMENT

With reference now to the drawings, the preferred embodiments of the LED chip and method of manufacture are herein described. It should be noted that the articles “a,” “an,” and “the,” as used in this specification, include plural referents unless the content clearly dictates otherwise.

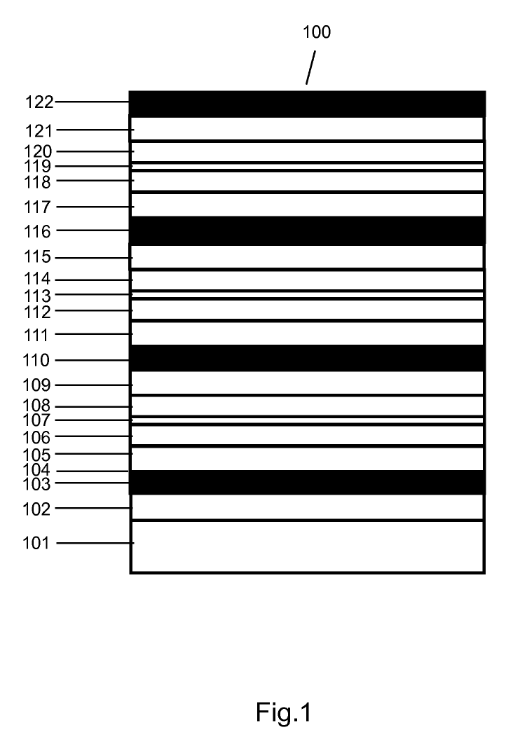

FIG. 1 depicts the epitaxial structure 100 of a multiple color emitting LED chip manufactured using a one step metal organic chemical vapor deposition (MOCVD) process. The resultant LED has three emitting structures, layered one on top of the other with an isolation or dielectric layer between emitting structures. The three emitting structures may emit any color of light, though the preferred embodiment would have structures that emit red, green, and blue light, respectively. The ordering on the structures is not critical to the invention and the light color may be in any order, however, for the purposes of this Application, the example given shall be deemed to have a top structure emitting blue, the middle emitting green and the bottom structure emitting red.

The epitaxial structure 100 includes three substructures to emit red, green, and blue color, respectively, which are built on top of one substrate 101. Each structure is isolated by an insulating layer. Substrate 101, which can be Si, GaAs, GaN, AlN, SiC, Sapphire, or some other suitable material, is used as the base for the LED structure. Buffer layer 102 is positioned on substrate 101 to eliminate lattice mismatch defects. This buffer layer 102 can be GaN or AlN and can also use the technologies disclosed in U.S. Pat. No. 6,815,241, this patent being incorporated herein by reference. Buffer layer 102 is covered by an isolation layer or dielectric layer 103, which can also be GaN or AlN.

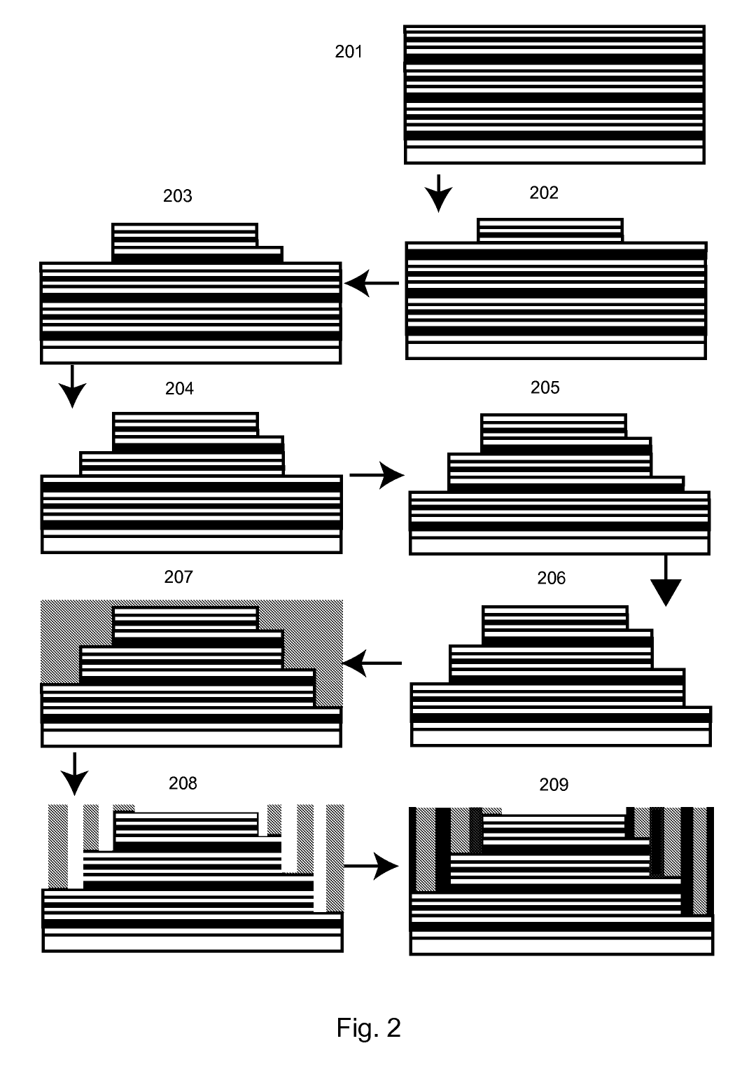

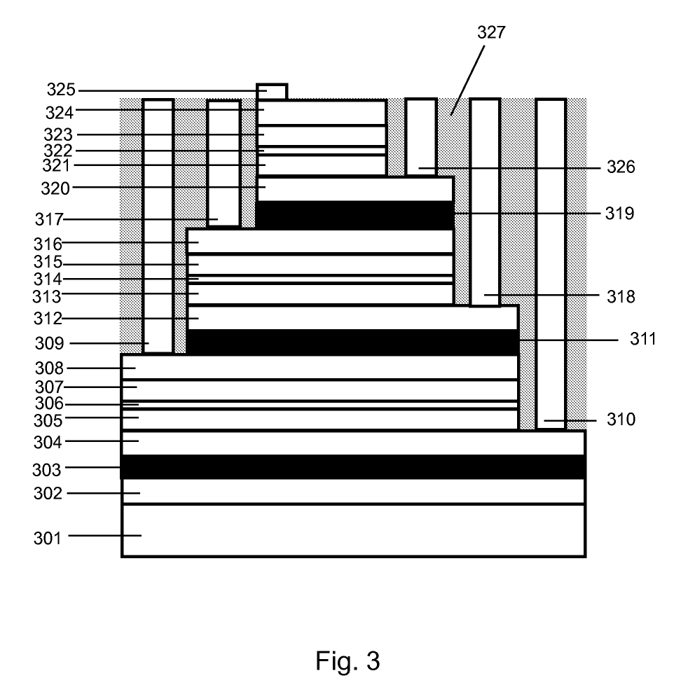

The three sub-structures are now layered on top of the substrate structure. Each substructure comprises an initial contact layer, a first cladding layer, at least one emission layer(s), a second cladding layer, and a second contact layer. For the initial substructure, 105 is the contact layer for electrical contact, which can be GaN, AlGaN, or GalnN. This layer is heavily doped, either N+ or P+, for contacting purpose. This layer can be coated with reflection layer 104 to reflect all light away from the substrate. The first cladding layer for red color emission is 106 and this layer can be GaN, AlGaN, GalnN, or GaNP. The emitting or active layer for red color 107 may be GaInP, AlGaInP, GaInN, or GaNP. The active layer can consist of multiple quantum wells with materials of GaInP, AlGaInP, GaInN, or GaNP. The second cladding layer 108 may be GaN, AlGaN, GaInN, or GaNP. The second contact layer 109 for electrical contact may be GaN, AlGaN, or GaInN. This layer is also heavily doped, either N+ or P+, for contacting purpose. The structure from layer 106 to 109 emits a red color. On top the red color structure, a structure to emit a green color is constructed, using a similar layering technique. Between the structures is a semi-insulating layer or dielectric layer 110, which can be GaN, AlN, or other proper materials. First contact layer 111, which can be GaN, AlGaN, GaInN, or GaNP, is positioned over the insulating layer and the first cladding layer for green color emission 112 positioned on top of first contact layer 111. The first cladding layer for green emission may be GaN, AlGaN, AlGaInN, GaInN, or GaNP. The emitting or active layer for green color 113 is positioned on top of the fist cladding layer 112 and can be AlGaInN, AlGaN, or GaInN. The emitting layer can consist of multiple quantum wells with materials of AlGaInN, AlGaN, or GaInN. The emission layer 113 is covered with the second cladding layer for green color emission 114 and second contact layer 115 respectfully. The second cladding layer for green color emission 114 may be GaN, AlGaInN, AlGaN, GaInN, GaNP and the second contact layer may be GaN, AlGaN, or GaInN. This second contact layer 115 is heavily doped, either N+ or P+, for contacting purposes. The structure from layer 111 to 115 emits the green color. On top of the green emitting structure, a structure emitting blue color is constructed. The structure, comprising layers 117 through 121, follows the same pattern as the green and red structures. First is a semi-insulating layer or dielectric layer 116, which can be GaN or AlN or other proper materials, is formed over the second green contact layer 115, then the blue structure is built. First contact layer 117 may be formed from GaN, AlGaN, GaInN, or GaNP. First cladding layer 118 can be GaN, AlGaN, AlGaInN, GaInN, or GaNP. The emitting or active layer for blue color 119, which can be AlGaInN, or GaInN, is formed on top of the first blue cladding layer 118 and covered by second blue cladding layer 120, which may, like the first blue cladding layer be formed from GaN, AlGaN, AlGaInN, GaInN, or GaNP. The active layer consists of multiple quantum wells with materials of AlGaInN or GaInN. The second contact layer for electrical contact 121 may be GaN, AlGaN, GaNP, or GaInN. Like previous contact layers, layers 117 and 121 should be heavily doped, either N+ or P+, for contacting purposes. The final structure is covered with another insulation layer or dielectric layer 122. This final dielectric layer 122 may be entirely removed, as shown in following the sections depicted in FIGS. 2 and 3.

It should be noted that the chemical composition of each layer is given for the preferred embodiment, that is for an LED chip that will emit red, blue, green or white (when all three regions are activated) light. The chemical composition of any layer may be altered by using equivalent compounds for the colors disclosed or by using any compound for any desired color (i.e. orange, yellow, violet, etc). Likewise, any number of emitting structures may be utilized. The method according to the present invention could be used to make a five, seven, or more colored LED chip just by adding emitting structures of appropriate chemical composition for the colors desired. It should also be noted that the active layer in each emitting structure may actually be a plurality of layers acting in concert, rather than just a single layer. In any event, the addition of layers and structures merely repeats the method described herein for the addition of any additional layer or structure.

FIG. 2 depicts the process to produce the LED chip structure. The first step 201 is to use a one step epitaxial process to produce an overall LED structure like the one depicted in FIG. 1. Then, steps 202 is a first litho and etch process to create one electrical contact area for blue LEDs. Step 203 is a second litho and etch to create another electrical contract are for blue LED and one electrical contact area for green LED. Step 204 is to create anther electrical contact area for green LED. Step 205 is to create one electrical contact area for red LED. Step 206 is to create another electrical contact area for the red LED. Step 207 is to deposit metals for contact areas, which is then etched in Step 208 to form electrodes for different LED structures. Step 209 is to deposit dielectric materials to fill the gap between electrodes and form the final structure.

FIG. 3 depicts the cross section of final structure of the integrated LED, where 301 is the base substrate, 302 is a buffer layer, and 303 is semi-insulating layer. In a first emitting structure, 304 is the first contact layer for the red LED, 305 is first cladding layer for the red LED, 306 is the emitting layer of the red LED, 307 is a second cladding layer for red LED, and 308 is a second contact layer for the red LED. Electrodes 309, 310 are also provided for the red LED layer. A semi-insulating layer 311 is provided between the first, red, emitting structure and the second, green one. The layering continues in the disclosed pattern for the emitting structures, where 312 is the first contact layer for the green LED, 313 is first cladding layer for the green LED, 314 is the emitting layer of the green LED, 315 is the second cladding layer for the green LED, and 316 is second contact layer for the green LED. Like the first layer, electrodes 317, 318 are provided for the second, green LED emitting structure and 319 is semi-insulating layer between the second, green, emitting structure and the third, blue one. Again, the layering repeats for the blue LED, where 320 is the first contact layer for the blue LED, 321 is the first cladding layer for the blue LED, 322 is the emitting layer of the blue LED, 323 is the second cladding layer for the blue LED, and 324 is the second contact layer for the blue LED. Electrodes 325, 326 are provided for the blue LED. Dielectric materials 327 isolate all of the electrodes.

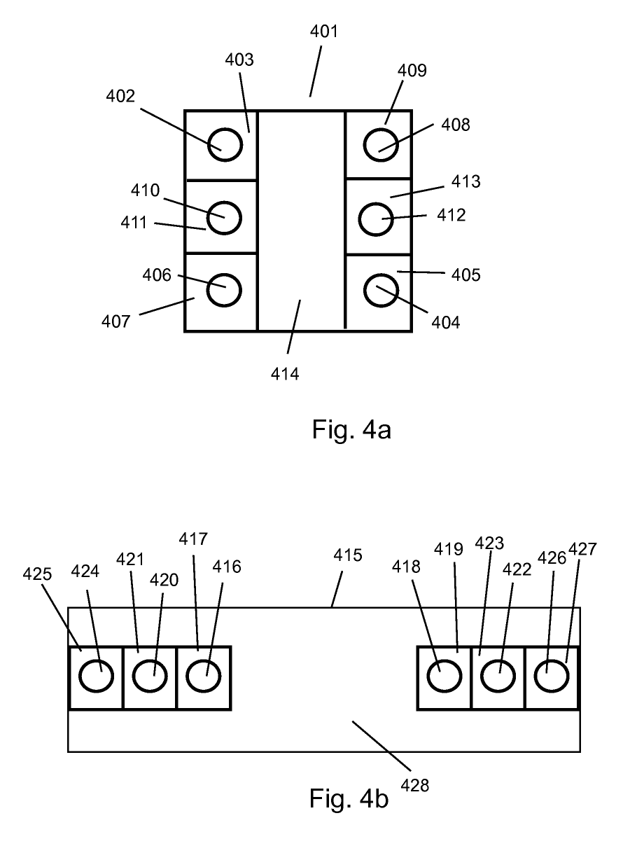

FIGS. 4a and 4b each depict the top view of different LED configurations. In FIG. 4a, 401 is an LED with a vertical electrode structure. Electrodes 402 and 404 are the electrodes for the blue LED structure, with isolation pads 403, 405 surrounding the electrodes 402, 404 respectively. The configuration for the green and red structures are similar, with 406 and 408 being the electrodes for the green LED structure, surrounded by isolation pads 405 and 407. The red structure's electrodes 410 and 412 are likewise surrounded by isolation pads 411 and 413. The emitting area 414 lies encompassed by the electrodes.

FIG. 4b depicts the LED configuration shown in FIG. 3 as a final product where 415 is the structure. Electrode 416 and 418 are connected to the blue LED and are surrounded by isolation pads 417 and 419. The green LED is connected to electrodes 420 and 422, each being surrounded by isolation pads 421 and 423. Red LED is connected to electrodes 424 and 426. These electrodes are isolated by pads 425 and 427 respectively. The resultant emitting area 428 is, as a result of this configuration, very broad.

Although the present invention has been described with reference to preferred embodiments, numerous modifications and variations can be made and still the result will come within the scope of the invention. No limitation with respect to the specific embodiments disclosed herein is intended or should be inferred.

What is claimed is:

1. A method of forming a multi-color emitting LED chip, the process comprising: forming a base chip through a one-step epitaxial process; specifically by forming a plurality of light emission substructures on a substrate, each substructure layered one on top of another with isolation layer in between each other and each light emission substructure being capable of emitting a different color of light.

2. A multi-colored LED chip formed using the method of claim 1.

3. The method of claim 1, further comprising:
a. selectively and partially removing layers of the base chip at given locations;
b. replacing removed layers with an electrically conductive material;
c. etching the electrically conductive material to form electrical connectors; and
d. replacing removed electrically conductive material with an electrically insulating material.

4. A multi-colored LED chip formed using the method of claim 3.

5. The method of claim 1, each light emission substructure comprising two electrically conductive layers and the step of selectively and partially removing layers of the base chip being made in a manner to expose each electrically conductive layer for contact with the electrically conductive material, wherein each light emission substructure can be independently activated and also activated in tandem with any other light emission substructure.

6. An LED chip formed by the method of claim 5.

7. An LED chip comprising:
a. a substrate structure; the substrate structure further comprising:
i. a substrate;
ii. a buffer layer on one side of the substrate to reduce lattice mismatch defects between the substrate and an epitaxial layer; and
iii. a substrate dielectric layer; and
b. a plurality of color emission structures, each color emission structure further comprising:
i. a lower contact layer for establishing electrical contact;
ii. an underside cladding layer;
iii. at least one color emission active layer capable of emitting light;
iv. a topside cladding layer; and
v. an upper contact layer for establishing electrical contact; and
c. at least one dielectric layer;
wherein each color emission structure emits a wavelength of light unique compared to other color emission structures and the substrate structure and color emission structures are layered, with each color emission structure positioned on a top side of an immediately lower structure and having at least one dielectric layer between said color emission structures.

8. The LED chip of claim 7, one of the color emission structures emitting a red light.

9. The LED chip of claim 7, one of the color emission structures emitting a green light.

10. The LED chip of claim 7, one of the color emission structures emitting a blue light.

11. The LED chip of claim 7, capable of emitting a white light when all of the color emission structures are activated.

12. The LED chip of claim 7, further comprising a plurality of electrically conductive contacts, one attached operatively to each contact layer in each color emission structure and all of the electrically conductive contacts being electrically insulated from each other.

13. The LED chip of claim 12, one of the color emission structures emitting a red light.

14. The LED chip of claim 12, one of the color emission structures emitting a green light.

15. The LED chip of claim 12, one of the color emission structures emitting a blue light.

16. The LED chip of claim 12, capable of emitting a white light when all of the color emission structures are activated.

17. The LED chip of claim 12, each color emission structure being capable of being activated both independently from each other color emission structure and in combination with any number of other color emission structures.

18. The LED chip of claim 17, one of the color emission structures emitting a red light.

19. The LED chip of claim 17, one of the color emission structures emitting a green light.

20. The LED chip of claim 17, one of the color emission structures emitting a blue light.

21. The LED chip of claim 17, capable of emitting a white light when all of the color emission structures are activated.
